(19) United States
(12) Patent Application Publication
(10) Pub. No.: US 2009/0059623 A1
(43) Pub. Date: Mar. 5, 2009

(54) Switched-mode Power Supply With EMI Isolation

(76) Inventor: Jun Cai, Mather, CA (US)

Correspondence Address: Jun Cai, 11012 Foxmouth Circle, Mather, CA, 95655, US

(21) Appl. No.: 11/847,320

(22) Filed: Aug. 29, 2007

(51) Int. Cl. H02M 3/335; H05K 9/00

(52) U.S. Cl. 363/21.02; 363/21.01

(57) ABSTRACT

Embodiments disclosed herein describe a switched-mode power supply with the EMI isolated from a input power, by disconnecting the input power from the switched-mode power supply when the switched-mode power supply is switching.

### CROSS REFERENCE TO RELATED APPLICATIONS

Not applicable.

### FIELD OF INVENTION

This invention relates to a SMPS (switched-mode power supply) with its EMI(electro-magnetic interference) isolated from the input power.

### BACKGROUND OF INVENTION

A SMPS (switched mode power supply) usually generates a lot of EMI (electro-magnetic interference) during operation. This is because during operation the SMPS turns on and off its switch rapidly which causes voltages and or currents to change rapidly. These rapidly changing voltages and or currents will result in EMI. This EMI can be coupled back to the input power for the SMPS, such as an AC power line of an AC-DC converter, or a category 5 cable connected through a RJ45 connector in a POE (power over Ethernet) application. The EMI in the power line or the cable will cause the failure of conducted EMC (electro-magnetic compatibility) required by, for example, FCC Part 15. And to make things worse, the power line or the cable can act as an antenna for the EMI signal to radiate so it can also cause the failure of radiated EMC.

To pass the conducted and radiated EMC, some prior arts tried to reduce the generation of the EMI from the SMPS. Some prior arts used a snubber circuit to absorb part of the switching energy of the SMPS, but it can not reduce the EMI very effectively. Many prior arts used a low pass filter to filter the input power for the SMPS, but this requires bulky inductor and capacitor. And another method disclosed by the U.S. Pat. No. 5,790,390 and U.S. Pat. No. 6,295,212 was to detect an AC input power voltage and let the SMPS only operate when the AC input power was at its negative half cycle while the AC input power was not effectively connected to the SMPS. This method required an AC input power and did not work for a DC input power. And since the SMPS only operated when the AC input power was at its negative half cycle, it limited the amount of power the SMPS could deliver.

Hence it is highly desirable to improve techniques for a SMPS to pass the EMC requirements.

This invention disclosed methods and structures to help a SMPS to pass the EMC requirements. The method and structure disclosed in this invention do not limit the input power to be only an AC input power as prior arts did, but can also work in a DC input power condition. Also when working with an AC input power, the method and structure disclosed in this invention do not limit the SMPS to only operate during the negative half cycle of the AC input power as prior arts did, instead the SMPS in this invention can operate in the full cycle of the AC input power so it can increase the power the SMPS can deliver.

### SUMMARY

A SMPS(switched-mode power supply) usually has an energy transfer element like a transformer connected to a power switch. During its operation when rapidly switching on and off its power switch, the SMPS usually generates a lot of EMI(electro-magnetic interference) which can be coupled back to the input power, such as an AC input power line or a category 5 cable delivering the DC power. This EMI will cause failure for conducted and or radiated EMC(electro-magnetic compatibility).

The methods and structures disclosed by this invention are to disconnect the SMPS from its input power when the SMPS is switching. Instead of detecting the input power voltage and using it to control and disconnect the input power from the SMPS as prior arts did, The methods and structures disclosed in this invention use the switching signal controlling the power switch of the SMPS which is usually already available from the SMPS, to control and disconnect the input power from the SMPS when the SMPS is switching, so they can be applied to both DC and AC input power conditions.

One embodiment showed in this invention includes a DC input power with a flyback type SMPS. Its typical application can be a POE (power over Ethernet) application where the input power is an approximately 48 volt DC voltage coming from an Ethernet category 5 cable. The SMPS converts this DC input power to lower DC voltages as outputs.

Another embodiment showed in this invention includes an AC input power with a flyback type SMPS. Its typical application can be an AC-DC adaptor or charger.

One of the objectives of this invention is to get rid of the bulky low pass filter at a SMPS's input power, which was previously needed to filter the EMI to pass the EMC requirements.

### BRIEF DESCRIPTION OF THE DRAWINGS

Embodiments of the invention relating to both structures and methods of operation may best be understood by referring to the following descriptions and accompanying drawings:

FIG. 1A shows an embodiment with DC input power;

FIG. 1B shows the waveforms for the embodiment in FIG. 1A;

FIG. 2 shows an embodiment with AC input power.

### DETAILED DESCRIPTION

A SMPS (switched-mode power supply) usually has an energy transfer element, such as an inductor or a transformer, connected to an input power through a or a group of power switches. The power switch is controlled by a switching signal and when the power switch turns on, the energy will transfer from the input power to and be stored in the energy transfer element. And when the power switch turns off, the energy stored in the energy transfer element will be transferred, at least partially, to the SMPS output. The fast switching of the SMPS's power switch will generate EMI(electro-magnetic interference) which can be coupled back to the input power to cause failure for conducted and or radiated EMC (elelctro-magnetic compatibility) requirements.

This invention discloses methods and structures to isolate the EMI generated by a SMPS from the SMPS's input power, thus help pass the EMC requirements. The methods and structures disclosed in this invention use the switching signal of the SMPS's power switch, which is usually available from the SMPS, and use it to generate a control signal to disconnect the SMPS from its input power when the power switch is switching. The methods and structures disclosed by this invention can be applied to any types of SMPS, such as, but not limited to, buck, boost, flyback, forward, push-pull, bridge, cuk, resonance, SEPIC and charge pump type SMPS, also can be applied to both DC and AC input power conditions. While the invention is susceptible to various SMPS types, various kind of input powers, and alternative structures and methods, specific embodiments thereof have been shown by way of example in the drawings and will be described in detail herein. However it should be understood that it is not intended to limit the invention to the particular types, structures and methods disclosed, but on the contrary, the intention is to cover all the structure and method modifications, equivalents and alternatives falling within the scope of the invention defined by the appended claims.

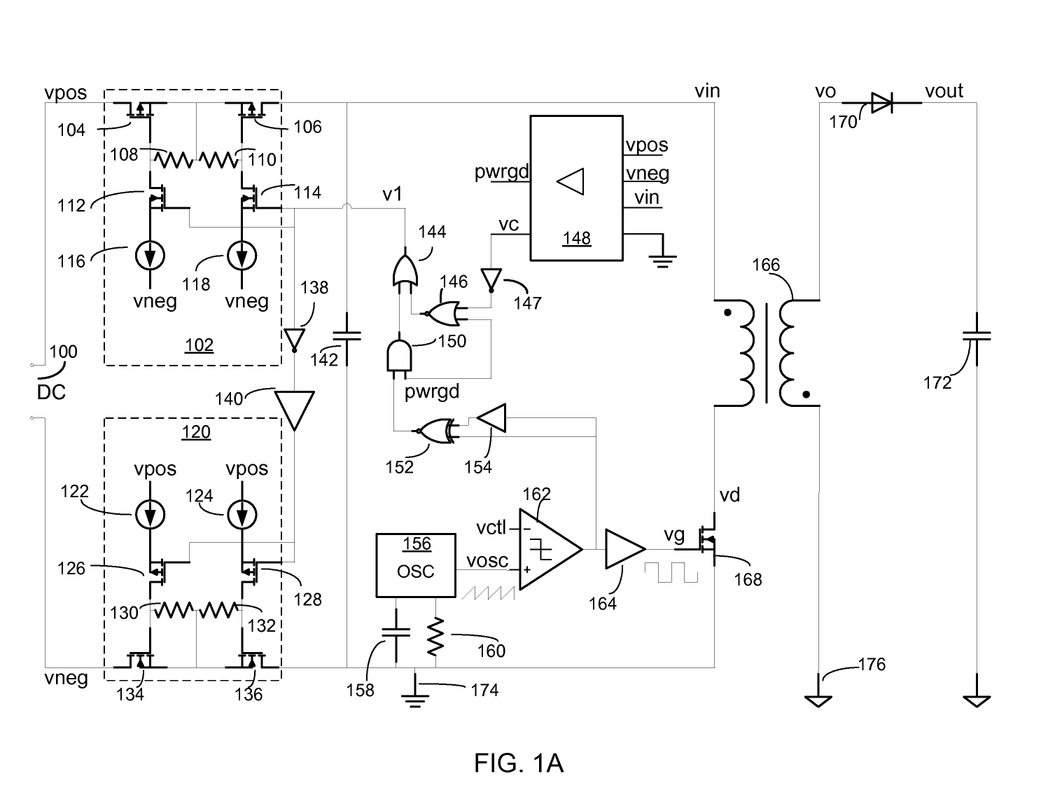

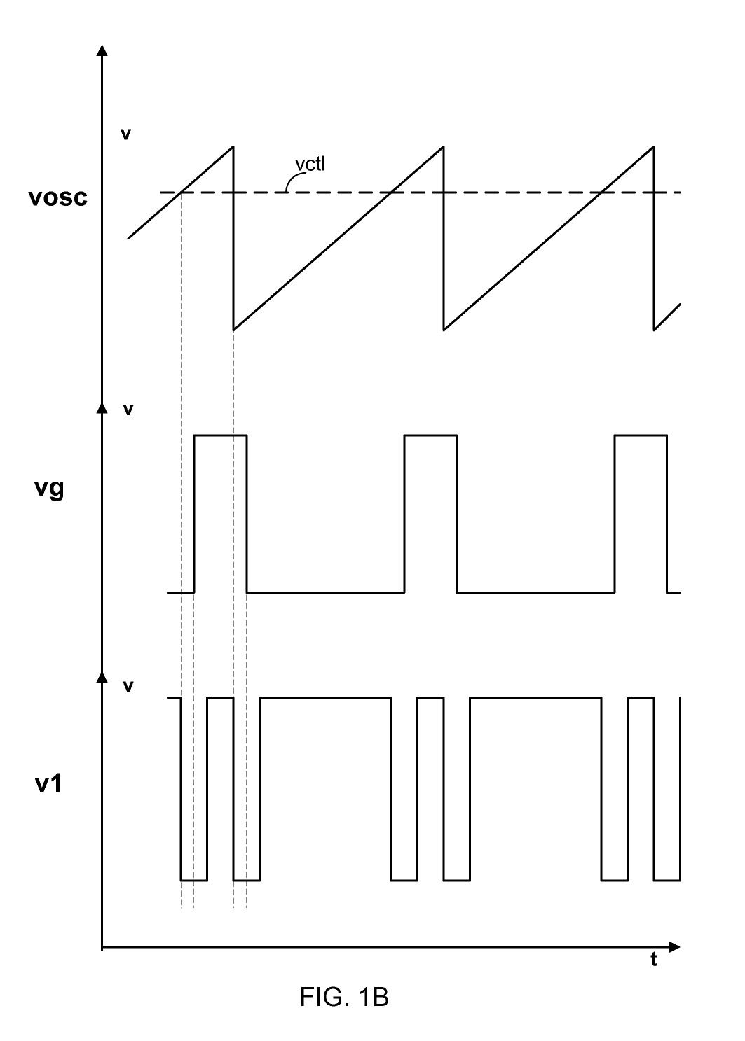

FIG. 1A shows an embodiment of the invention which includes a flyback type SMPS and a DC input power. FIG. 1B shows the waveforms for the embodiment in FIG. 1A. In FIG. 1A, the embodiment includes an energy transfer element which is a transformer 166 in this embodiment, connected to a NMOS power switch 168, and they together are connected between a primary side ground 174 and a node vin. There is also an oscillator circuitry 156 which generates a sawtooth waveform with period depending on a capacitor 158 and a resistor 160 connected to the oscillator circuitry 156. The output of the oscillator circuitry 156 is connected to a node vosc and compared to the voltage at a node vctl by using a comparator 162, to generate a switching control signal vg through a delay element 164 to control the NMOS power switch 168. The voltage value of the vctl will determine the on time of the NMOS power switch 168 and thus the power delivered by the transformer 166 to its output, and can be adjusted according to a feedback circuitry which is not shown here. There are also a diode 170, and a capacitor 172 which is connected between the diode 170 and a secondary side ground 176. The output side of the transformer 166 is connected to the diode 170 and the secondary side ground. Above elements constructs a typical flyback type SMPS with its input side connected to the node vin and the primary side ground 174.

The embodiment in FIG. 1A also includes a DC input power 100 with a positive voltage node vpos and a negative voltage node vneg. The vpos is coupled to the vin through a so-called high-side switch 102. The vneg is coupled to the primary side ground 174 through a so-called low-side switch 120. The high-side switch 102 and low-side switch 120 will be disconnected when the NMOS power switch 168 is switching on or off. The high-side switch 102 includes a current source 116 and a current source 118 which are connected to the gates of a PMOS transistor 104 and a PMOS transistor 106 through a NMOS transistor 112 and a NMOS transistor 114. The PMOS transistor 104 and the PMOS transistor 106 have their sources and substrates connected in the way shown so their parasitic body diodes are back-to-back connected to prevent the vpos and the vin from being connected through these body diodes. The gates of the NMOS transistor 112 and the NMOS transistor 114 are both tied to a control signal v1. When the v1 goes high, the NMOS transistor 112 and the NMOS transistor 114 turn on and currents of the current source 116 and the current source 118 will be drawn through a resistor 108 and a resistor 110 from the sources of the PMOS transistor 104 and the PMOS transistor 106. The currents will cause voltage differences between the gates and the sources of the PMOS transistor 104 and the PMOS transistor 106 and will turn on the PMOS transistor 104 and the PMOS transistor 106, thus the high-side switch 102 is turned on and the vpos and the vin are connected. When the v1 goes low, the NMOS transistor 112 and the NMOS transistor 114 turn off and there will be no current flowing through the resistor 108 and the resistor 110, so there will be no voltage difference between the gates and the sources of the PMOS transistor 104 and the PMOS transistor 106, and the PMOS transistor 104 and the PMOS transistor 106 will be turned off, thus the high-side switch 102 is turned off and the vpos and the vin are disconnected.

In FIG. 1A, it is very similar for the low-side switch 120 which includes a current source 122, a current source 124, a PMOS transistor 126, a PMOS transistor 128, a resistor 130, a resistor 132, a NMOS transistor 134 and a NMOS transistor 136. The gates of the PMOS transistor 126 and the PMOS transistor 128 are both tied to the v1 through an inverter 138 and a level-shifter 140. Similarly when the v1 goes high, the NMOS transistor 134 and the NMOS transistor 136 will be turned on thus the low-side switch 120 will be turned on and the vneg and the primary side ground 174 are connected. When the v1 goes low, the NMOS transistor 134 and the NMOS transistor 136 will be turned off thus the low-side switch 120 is turned off and the vneg and the primary side ground 174 are disconnected.

The embodiment in FIG. 1A also includes an energy storage element which is a capacitor 142 in this embodiment. The capacitor 142 connects between the vin and the primary side ground 174. When the high-side switch 102 and the low-side switch 120 turn on, the energy from the DC input power 100 transfers to the capacitor 142. When the high-side switch 102 and the low-side switch 120 turn off, the capacitor 142 will transfer its energy, at least partially, to the transformer 166 when the power switch 168 is on. In FIG. 1A, the output of the comparator 162, which is an early version of the switching signal vg, goes through a XNOR gate 152, a delay element 154, a AND gate 150 and a OR gate 144 to connect to the v1. Thus every time the vg is switching, either high or low, the v1 will have a logic low pulse to turn off the high-side switch 102 and the low-side switch 120. The logic low pulse width depends on the delay element 154, and the delay element 164 is used to guarantee the logic low pulse can cover the whole rising and falling edge of the vg. This can be seen in FIG. 1B. Thus when the NMOS power switch 168 is in a transition, either switching on or off, the high-side switch 102 and the low-side switch 120 are disconnected so the EMI generated at these fast transition or switching moments will be confined within the SMPS and will not be coupled to the DC input power 100.

The embodiment in FIG. 1A also includes a startup circuitry 148 which takes the vpos, the vneg, the vin and the primary side ground 174 as inputs and outputs a control signal vc and a control signal pwrgd. During the startup phase, the startup circuitry 148 monitors the voltage values of the vpos, the vneg and the vin. At first when there are valid voltages at the vpos and the vneg but there is no valid voltage on the vin and the primary side ground, the startup circuitry 148 outputs the pwrgd with logic low which means the power is not ready yet and the pwrgd will reset the circuitries of the SMPS, such as the oscillator circuitry 156, the comparator 162, the delay element 164, and prevents these circuitries from operating. Meanwhile, the vc from the startup circuitry 148 will turn high from low after a predetermined time (for example, after all the bias voltages and currents are ready), and through a 147, a NOR gate 146 and the OR gate 144, to control the v1 to turn on the high-side switch 102 and the low-side switch 120 to start to charge the capacitor 142. After the charging is finished and the voltage on the capacitor 142 is equal to the valid voltage of the DC input power 100, then the pwrgd will turn logic high which means the power is good and it will start the SMPS circuitries which were held before in startup phase and meanwhile bypass the vc so now the v1 is controlled by the early version of vg. So the NMOS power switch 168 will start to switch and the transformer 166 will start to deliver power to its output, and every time when the NMOS power switch 168 is switching, either switching high or low, the high-side switch 102 and the low-side switch 120 are disconnected so the EMI is isolated from the DC input power 100.

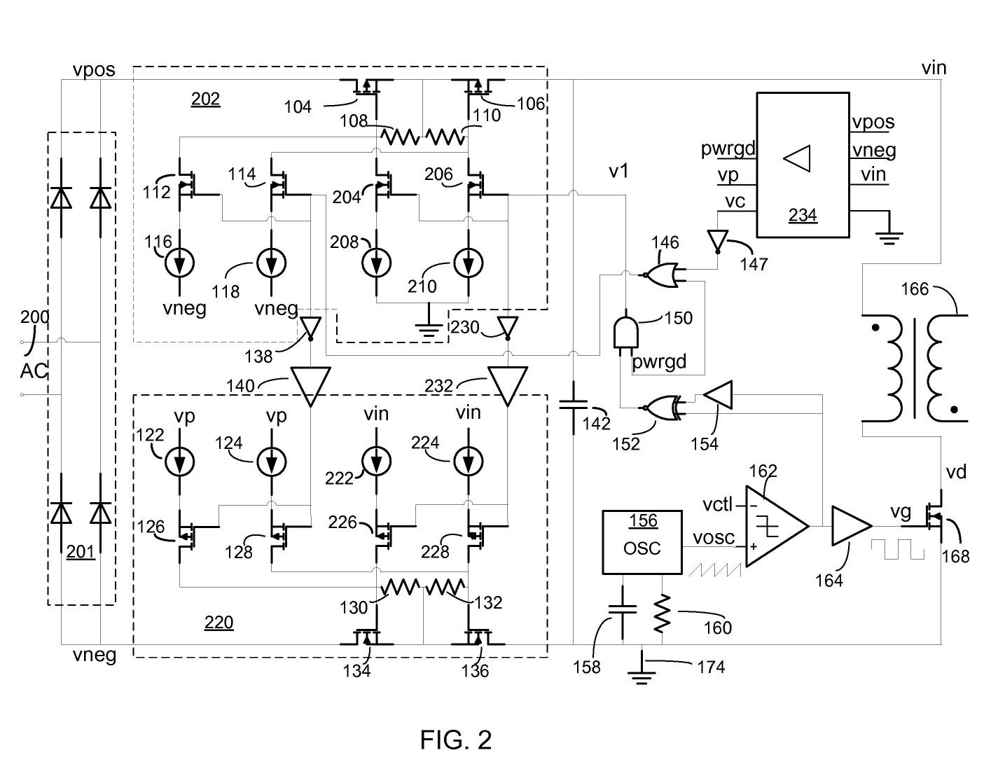

As mentioned before, the input power can also be an AC input power which can be rectified by, for example, a diode or a group of diodes to provide the input power. A rectified AC input power in parallel with a capacitor can easily replace the DC input power 100 in FIG. 1A. The input power can also be a rectified AC input power without a capacitor in parallel. The basic operation will be the same as that shown in FIG. 1A with a DC input power. The difference will be in the startup phase. FIG. 2 shows an embodiment which includes a flyback type SMPS and an AC input power rectified by a diode bridge.

The embodiment shown in FIG. 2 has a similar flyback type SMPS( as in FIG. 1A) which includes the transformer 166, the NMOS power switch 168, the primary side ground 174, the oscillator circuitry 156, the comparator 162 and the delay element 164. The elements at the right side of the transformer 166( as shown in FIG. 1A) are omitted here to save some space for the drawing. In FIG. 2, an AC input power 200 is rectified and coupled to the vpos and the vneg through a diode bridge rectifier 201. The vpos is coupled to the vin through a high-side switch 202 (instead of the high-side switch 102 in FIG. 1A) and the vneg is coupled to the primary side ground 174 through a low-side switch 220 (instead of the low-side switch 120 in FIG. 1A). In addition to the elements in the high-side switch 102 in FIG. 1A, the high-side switch 202 in FIG. 2 also includes a NMOS transistor 204, a NMOS transistor 206, a current source 208 and a current source 210. During startup phase, the NMOS transistor 204 and NMOS transistor 206 will be held off and the NMOS transistor 112 and the NMOS transistor 114 will be controlled by the vc and turn on to turn on the high-side switch 202. After startup phase and during the normal operation, the NMOS transistor 112 and NMOS transistor 114 will be held off and the NMOS transistor 204 and the NMOS transistor 206 will be controlled by the v1 to turn on and off the high-side switch 202. In FIG. 2 there is also a startup circuitry 234 (which is similar to the startup circuitry 148 in FIG. 1A). The startup circuitry 234 in FIG. 2 generates the pwrgd, the vc and a voltage vp. The vp is a positive bias voltage which is used for the current source 122 and the current source 124 in the low-side switch 220.

In FIG. 2 the low-side switch 220 includes a current source 222, a current source 224, a PMOS transistor 226, a PMOS transistor 228 and all the elements included in the low-side switch 120 in FIG. 1A. Similar as in the high-side switch 202, in the low-side switch 220, the PMOS transistor 226 and the PMOS transistor 228 are held off during startup and controlled by the v1 through an inverter 230 and a level-shifter 232 during normal operation to turn on and off the low-side switch 220. The PMOS transistor 126 and the PMOS transistor 128 are held off during normal operation and only turn on during the startup phase. During the startup phase, the vin and the primary side ground 174 may not have the desired voltages, so the current source 116 and the current source 118 are connected to the vneg instead of the primary side ground 174, and the current source 122 and the current source 124 are connected to the vp instead of the vin. During the normal operation, the voltages at the vpos and the vneg can vary a lot since they are connected to a rectified AC input power, so the current source 208 and the current source 210 are connected to the primary side ground 174 instead of the vneg, and the current source 222 and the current source 224 are connected to the vin instead of the vpos.

In FIG. 2, at the beginning of startup phase, the control signal pwrgd is logic low and the control signal vc will start to turn logic high from logic low at a predetermined time (for example, after all the bias voltages and currents are ready). This will turn on the high-side switch 202 (by turning on the NMOS transistor 112 and the NMOS transistor 114) and the low-side switch 220 (by turning on the PMOS transistor 126 and the PMOS transistor 128) and the AC input power 200 starts to charge the capacitor 142. After the charging is finished and the voltage on the capacitor 142 has reached a predetermined value, the pwrgd will turn high, which will enable the normal operation of the SMPS and meanwhile shut off the NMOS transistor 112, the NMOS transistor 114, the PMOS transistor 126 and the PMOS transistor 128. So the NMOS power switch 168 will start to switch on and off, and the transformer 166 will start to transfer power to its output, and every time when the NMOS power switch 168 is switching, either switching high or switching low, the high-side switch 102 and the low-side switch 120 are disconnected so the EMI is isolated from the AC input power 200.

While the present disclosure describes above several embodiments, these embodiments are to be understood as illustrative and do not limit the claim scope. The structure and method disclosed in this invention can have many variations and modifications such as:
Can have different types of SMPS, such as, but not limited to: buck, boost, flyback, forward, push-pull, bridge, cuk, resonance, SEPIC or charge pump type SMPS; Isolated or non-isolated SMPS;
Can have different types of input power, such as, but not limited to: DC input power, rectified AC input power or others;
Can have different types of the high-side switch and the low-side switch which can be made of different devices, such as, but not limited to: MOS transistor, BJT or SCR (silicon-controlled rectifier) or any combinations of them;
Any combinations of above.

Accordingly, the scope of the invention should be determined not by the embodiments illustrated, but by the appended claims and their legal equivalents.

What is claimed is:

1. An electronic circuit, comprising:
an input power,
a switched-mode power supply with an input side and an output side,
an energy storage element coupled to said input side of said switched-mode power supply,
said switched-mode power supply transferring energy from said energy storage element to its output side, and
switching means coupling said input power to said energy storage element,
said switching means disconnecting said input power from said energy storage element when said switched-mode power supply is in a transition to start or stop transferring energy from said energy storage element, and connecting said input power to said energy storage element for at least a portion of the time when the transition is finished,
whereby the EMI generated by said switched-mode power supply during the transition is isolated from said input power.

2. The electronic circuit of claim 1 wherein:
said input power is DC input power or rectified AC input power.

3. The electronic circuit of claim 1 wherein:
said switched-mode power supply is of buck, boost, flyback, forward, push-pull, bridge, cuk, resonance, SEPIC or charge pump type.

4. The electronic circuit of claim 1 wherein:
said switched-mode power supply is of isolated or non-isolated type, with or without its said output side regulated.

5. The electronic circuit of claim 1 wherein:
said energy storage element is a capacitor or a group of capacitors.

6. The electronic circuit of claim 1 wherein:
said input power has a positive voltage node and a negative voltage node,
said energy storage element has a positive voltage node and a negative voltage node, and
said switching means includes a high-side switch connecting said positive voltage node of said input power to said positive voltage node of said energy storage element, and a low-side switch connecting said negative voltage node of said input power to said negative voltage node of said energy storage element.

7. The electronic circuit of claim 6 wherein:
said high-side switch includes at least two PMOS transistors connected in series with their parasitic body diodes connected in back-to-back way,
said low-side switch includes at least two NMOS transistors connected in series with their parasitic body diodes connected in back-to-back way.

8. The electronic circuit of claim 1 further including:
operation control means to control said switching means to disconnect said input power from said energy storage element when said switched-mode power supply is in the transition to start or stop transferring energy from said energy storage element, and connecting said input power to said energy storage element for at least a portion of the time when the transition is finished.

9. The electronic circuit of claim 1 further including:
startup control means to control said switched-mode power supply, said energy storage element and said switching means to be able to start up properly.

10. A switched-mode power supply with EMI isolation, comprising:
an input power,
an energy transfer element with an input side and an output side,
at least one power switch coupled to said input side of said energy transfer element, and
an energy storage element coupled to said power switch and said energy transfer element,
said energy transfer element transferring energy, from said energy storage element, to its said output side as a result of said power switch turning on and off,
switching means coupled between said input power and said energy storage element, for connecting said input power to said energy storage element for at least a port of the time when said power switch is not switching, and disconnecting said input power to said energy storage element when said power switch is switching,
whereby the EMI generated when said power switch is switching is isolated from said input power.

11. The switched-mode power supply of claim 10 wherein:
said input power is DC input power or rectified AC input power.

12. The switched-mode power supply of claim 10 wherein:
said energy transfer element is transformer, inductor or capacitor.

13. The switched-mode power supply of claim 10 wherein:
said power switch is MOS transistor or BJT.

14. The switched-mode power supply of claim 10 wherein:
said energy storage element is a capacitor or a group of capacitors.

15. The switched-mode power supply of claim 10 wherein:
said input power has a positive voltage node and a negative voltage node,
said energy storage element has a positive voltage node and a negative voltage node, and
said switching means includes a high-side switch connecting said positive voltage node of said input power to said positive voltage node of said energy storage element, and a low-side switch connecting said negative voltage node of said input power to said negative voltage node of said energy storage element.

16. The switched-mode power supply of claim 15 wherein:
said high-side switch includes at least two PMOS transistors connected in series with their parasitic body diodes connected in back-to-back way,
said low-side switch includes at least two NMOS transistors connected in series with their parasitic body diodes connected in back-to-back way.

17. The switched-mode power supply of claim 10 further including:
control means to control said switching means to connect said input power to said energy storage element for at least a port of the time when said power switch is not switching, and to disconnect said input power to said energy storage element when said power switch is switching.

18. The switched-mode power supply of claim 10 further including:
startup control means to control said energy transfer element, said power switch, said energy storage element and said switching means to be able to start up properly.

19. A method to isolate the EMI of a switched-mode power supply from an input power, comprising steps of:
(a) connecting said input power to an energy storage element connected to said switched-mode power supply, to transfer energy from said input power to said energy storage element, when said switched-mode power supply is not in a transition to start or stop transferring energy from said energy storage element,
(b) disconnecting said input power from said energy storage element when said switched-mode power supply is in the transition to start or stop transferring energy from said energy storage element.
